(19) United States
(12) Patent Application Publication
(10) Pub. No.: US 2025/0212430 A1
(43) Pub. Date: Jun. 26, 2025

(54) SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Yoichi Hori, Himeji Hyogo (JP); Makoto Mizukami, Ibo Hyogo (JP)

(21) Appl. No.: 19/079,333

(22) Filed: Mar. 13, 2025

Related U.S. Application Data
(63) Continuation of application No. PCT/JP2024/005858, filed on Feb. 19, 2024.

(30) Foreign Application Priority Data
Jul. 13, 2023 (JP) 2023-115485

(51) Int. Cl. H10D 8/60; H10D 62/10; H10D 62/60; H10D 62/832; H10D 64/64

(52) U.S. Cl. CPC H10D 8/60; H10D 62/60; H10D 62/109; H10D 62/8325; H10D 64/64

(57) ABSTRACT

A semiconductor device according to an embodiment includes a SiC layer, which includes a first surface made up of a silicon plane and a second surface made up of a carbon plane; a plurality of protrusions, each of which includes a top face and side faces; a first electrode that forms Schottky junctions with the plurality of protrusions; a first semiconductor region of a first conductivity type provided in the SiC layer; a second semiconductor region of a second conductivity type provided among the plurality of protrusions in the SiC layer and located between the first semiconductor region and the first electrode; and a third semiconductor region of the first conductivity type provided in the side faces and located between the first electrode and the first semiconductor region in the protrusions, the third semiconductor region being higher in impurity concentration of the first conductivity type than the first semiconductor region.

### CROSS-REFERENCE TO RELATED APPLICATIONS

This application is based upon and claims the benefit of priority from the prior PCT Patent Application No. PCT/JP2024/005858, filed on Feb. 19, 2024, the entire contents of which are incorporated herein by reference, and which claims the benefit of priority to JP Application No. 2023-115485 files on Jul. 13, 2023, the entire contents of which are incorporated herein by reference.

### FIELD

Embodiments described herein relate generally to a semiconductor device.

### BACKGROUND

A Schottky barrier diode (SBD) made by joining together metal and a semiconductor is known as a semiconductor device. The SBD has the advantages of low forward voltage (V_{F}) and short reverse recovery time. Although the SBD has the disadvantage of a large leakage current (I_{R}) during application of a reverse bias a JBS (junction barrier Schottky diode) structure in which a p-type region is implanted in a surface of an n-type semiconductor layer is used to limit the leakage current. Furthermore, to reduce both the forward voltage and leakage current, it is a known practice to form a trench structure on a metal interface side of an n-type semiconductor layer.

To improve withstand voltage, silicon carbide (SiC) is used as a semiconducting material. However, with an SBD of a trench structure that uses SiC, characteristics of a Schottky junction differ between a surface and side faces of the trench, posing a problem in that a rising voltage (Vₜₕ) or a forward voltage disperses.

### BRIEF DESCRIPTION OF THE DRAWINGS

FIG. 1 is a cross sectional view of a semiconductor device according to a first embodiment.

FIG. 2 is an enlarged view of area A in FIG. 1.

FIG. 3 is a graph showing I_{F}-V_{F} characteristics of a Schottky barrier diode when a Schottky characteristics adjuster is not provided.

FIG. 4 is a graph showing I_{F}-V_{F} characteristics of a Schottky barrier diode in the semiconductor device according to the first embodiment.

FIG. 5 is a partial cross sectional view of a semiconductor device according to a second embodiment.

FIG. 6 is a graph showing I_{F}-V_{F} characteristics of a Schottky barrier diode in the semiconductor device according to the second embodiment.

FIG. 7 is a partial cross sectional view of a semiconductor device according to a third embodiment.

FIG. 8 is a partial cross sectional view of another semiconductor device to which the Schottky characteristics adjusters according to the first to third embodiments are applicable.

FIG. 9 is a partial plan view of the semiconductor device shown in FIG. 8.

FIG. 10 is a partial plan view of a semiconductor device provided with a high-concentration anode region having an octagonal planar shape.

### DETAILED DESCRIPTION

A semiconductor device according to an embodiment includes: a SiC layer, which includes a first surface and a second surface, the first surface being made up of a silicon plane, the second surface being made up of a carbon plane and placed opposite the first surface; a plurality of protrusions provided in the SiC layer, each of the protrusions including a top face and side faces, the top face being part of the first surface, the side faces being connected to the top face; a first electrode that forms Schottky junctions with the plurality of protrusions; a second electrode provided on the second surface; a first semiconductor region of a first conductivity type provided in the SiC layer; a second semiconductor region of a second conductivity type provided among the plurality of protrusions in the SiC layer and located between the first semiconductor region and the first electrode; and a third semiconductor region of the first conductivity type provided in the side faces of the protrusions and located between the first electrode and the first semiconductor region in the protrusions, the third semiconductor region being higher in impurity concentration of the first conductivity type than the first semiconductor region.

Embodiments of the present invention will be described below with reference to the drawings. The embodiments are not meant to limit the present invention. The drawings are schematic or conceptual, and ratios or the like among parts do not necessarily reflects actual ones. In the specification and drawings, components similar to those described earlier with reference to preceding drawings are denoted by the same reference signs as the corresponding components, and detailed description thereof will be omitted.

In the following description, to express relative levels of impurity concentration in the semiconductor regions, a notation made up of “n⁺”, “n”, “n⁻”, “p⁺”, “p”, and “p⁻” may be used, where “n⁺” is relatively higher in n-type impurity concentration than “n” and “n” is relatively lower in n-type impurity concentration than “n” while “p⁺” is relatively higher in p-type impurity concentration than “p” and “p⁻” is relatively lower in p-type impurity concentration than “p”. The n-type, the n⁺-type, and the n⁻-type are examples of a first conductivity type described in CLAIMS. The p-type, the p⁺-type, and the p-type are examples of a second conductivity type described in CLAIMS. Note that in the following description, the n-type and the p-type may exchange their names. That is, the p-type may be called the first conductivity type and the n-type may be called the second conductivity type.

Note that impurity concentration can be measured using, for example, SIMS (secondary ion mass spectrometry). The relative level of impurity concentration can be determined from the level of carrier concentration, which in turn can be found using, for example, SCM (scanning capacitance microscopy).

### First Embodiment

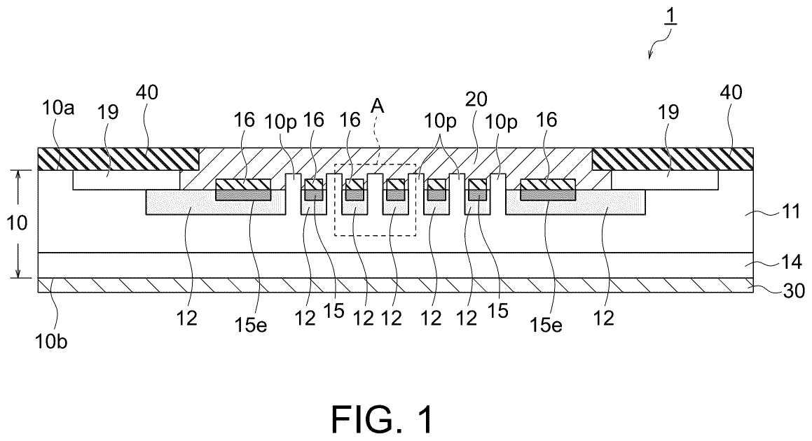

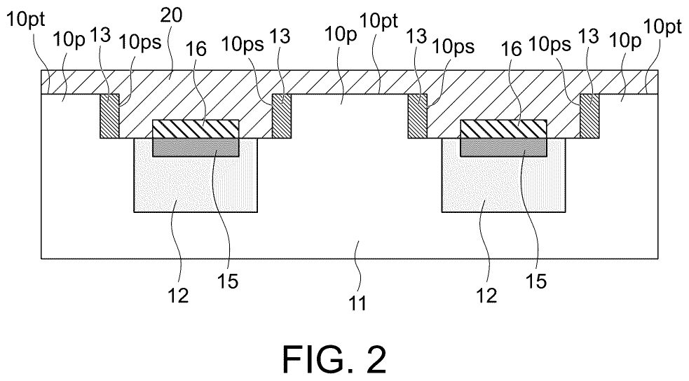

A semiconductor device according to a first embodiment will be described with reference to FIGS. 1 and 2. FIG. 1 is a cross sectional view of a semiconductor device 1 according to the present embodiment. FIG. 2 is an enlarged view of area A in FIG. 1. Note that FIG. 1 is a drawing common to second and third embodiments described later.

As shown in FIG. 1, the semiconductor device 1 includes a SiC layer 10, a silicide layer 16, an anode electrode 20, a cathode electrode 30, and a field oxide film 40. The semiconductor device 1 is a trench-type SBD obtained by forming a metal interface side of an n-type semiconductor layer into a trench structure, and more specifically, is a trench-type JBS in which a p-type semiconductor region is provided in the bottom of the trench.

The SiC layer 10 is made of single-crystal SiC (silicon carbide) such as 4H-SiC. Note that the SiC layer 10 may be an epitaxial layer or a semiconductor substrate, or may be made of a semiconductor substrate and an epitaxial layer provided thereupon. Besides, the SiC layer 10 may be made of another crystalline form such as 3C-SiC or 6H-SiC.

As shown in FIG. 1, the SiC layer 10 has a top surface 10a, and an undersurface 10b, which is a principal surface on the side opposite the top surface 10a. The top surface 10a is (0001) plane and the undersurface 10b is (000-1) plane. The (0001) plane may be called a silicon plane and the (000-1) plane may be called a carbon plane.

Note that the top surface 10a and undersurface 10b of the SiC layer 10 do not have to strictly match the (0001) plane and the (000-1) plane, respectively. For example, the top surface 10a is inclined with respect to the (0001) plane by 0 to 8 degrees (both inclusive) and the undersurface 10b is inclined with respect to the (000-1) plane by 0 to 8 degrees (both inclusive).

When it is said herein that a surface is “made up of a silicon plane,” the range described above is included. That is, when the top surface 10a is described as being made up of a silicon plane, the top surface 10a is a surface inclined with respect to the (0001) plane by 0 to 8 degrees (both inclusive). Similarly, when the undersurface 10b is described as being made up of a carbon plane, the undersurface 10b is a surface inclined with respect to the (000-1) plane by 0 to 8 degrees (both inclusive).

A plurality of protrusions 10p are provided in the SiC layer 10. The protrusions 10p appear when a plurality of trenches are formed in the top surface 10a of the SiC layer 10. Each of the protrusions 10p has a top face 10pt and side faces 10ps connected to the top face 10pt. The top face 10pt is part of the top surface 10a of the SiC layer 10, and is made up of a silicon plane. The silicide layers 16 are provided on surfaces (i.e., bottom surfaces of the trenches) connecting respective pairs of adjacent protrusions 10p.

A plurality of semiconductor regions, i.e., a drift region 11 of the first conductivity type, anode regions 12 of the second conductivity type, Schottky characteristics adjusters 13 of the first conductivity type, a cathode region 14 of the first conductivity type, a high-concentration anode regions 15 and 15e of the second conductivity type, and a reduced surface field region 19 of the second conductivity type are provided in the SiC layer 10.

The semiconductor regions of the first conductivity type contain, for example, nitrogen (N), phosphorus (P), arsenic (As), or antimony (Sb) as n-type impurities. The semiconductor regions of the second conductivity type contain, for example, aluminum (Al) or boron (B) as p-type impurities.

As shown in FIGS. 1 and 2, the anode electrode 20 is provided by implanting the plurality of protrusions 10p toward the top surface 10a of the SiC layer 10. The anode electrode 20 forms Schottky junctions with the plurality of protrusions 10p.

The anode electrode 20 includes titanium (Ti), molybdenum (Mo), vanadium (V), nickel (Ni), or a laminated film of titanium and aluminum (Ti/Al). Note that on an electrically conductive layer made of the above materials, the anode electrode 20 may have an electrically conductive layer (not illustrated) made of a material (such as copper or aluminum) different from the above materials.

The cathode electrode 30 is provided on the undersurface 10b of the SiC layer 10. The cathode electrode 30 forms an ohmic junction with the SiC layer 10 (cathode region 14 according to the present embodiment). The anode electrode 20 is, for example, a laminated film of titanium and aluminum (Ti/Al).

A field oxide film 40 is provided on the top surface 10a of the SiC layer 10, covering the reduced surface field region 19. The field oxide film 40 is made, for example, of a silicon oxide film.

Next, various semiconductor regions provided in the SiC layer 10 will be described.

The drift region 11 is an n-type semiconductor region provided in the SiC layer 10. The impurity concentration of n-type impurities in the drift region 11 is, for example, between 1×10¹⁵ cm⁻³ and 2×10¹⁶ cm⁻³ (both inclusive). The drift region 11 is an example of a first semiconductor region described in CLAIMS.

The anode regions 12 are p-type semiconductor regions provided among the plurality of protrusions 10p in the SiC layer 10. The anode regions 12 are located between the drift region 11 and the anode electrode 20. The anode regions 12 spread a depletion layer during application of a reverse bias, making it possible to reduce leakage current. The anode regions 12 are an example of a second semiconductor region described in CLAIMS.

The impurity concentration of p-type impurities in the anode regions 12 is, for example, between 5×10¹⁶ cm⁻³ and 5×10¹⁸ cm⁻³ (both inclusive). The anode regions 12 are formed, for example, by forming trenches in the top surface 10a of the SiC layer 10 and then ion-implanting the bottom surfaces of the trenches with p-type impurities.

The Schottky characteristics adjusters 13 are n-type or n⁺-type semiconductor regions provided in side faces 10ps of the protrusions 10p. The n⁺-type semiconductor regions are located between the anode electrode 20 and those parts of the drift region 11 which are inside the protrusions 10p. The impurity concentration of n-type impurities in the Schottky characteristics adjusters 13 is higher than the impurity concentration in the drift region 11, and is, for example, between 1×10¹⁶ cm⁻³ and 1×10²⁰ cm⁻³ (both inclusive). The Schottky characteristics adjusters 13 are an example of a third semiconductor region described in CLAIMS.

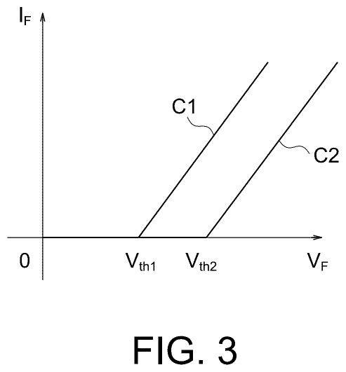

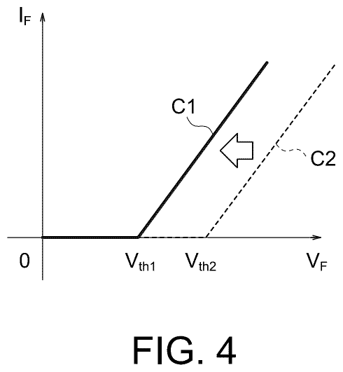

The Schottky characteristics adjusters 13 are provided to reduce Schottky barrier height (ϕ_{B}) on the side faces 10ps of the protrusions 10p and thereby bring the Schottky barrier height close to Schottky barrier height on the top face 10pt. More details will be described later with reference to FIGS. 3 and 4.

The Schottky characteristics adjusters 13 are formed by ion-implanting the side faces 10ps of the protrusions 10p (side faces of the trenches) with n-type impurities using a tilted ion implantation technique or the like. Alternatively, the Schottky characteristics adjusters 13 may be formed on the top surface 10a of the SiC layer 10 by forming a mask at ends of the protrusions 10p with openings provided in the mask and then ion-implanting n-type impurities through the openings.

The cathode region 14 is an n⁺-type semiconductor region located between the drift region 11 and the cathode electrode 30 in the SiC layer 10. The impurity concentration of n-type impurities in the cathode region 14 is, for example, between 1×10¹⁸ cm⁻³ and 1×10²¹ cm⁻³ (both inclusive).

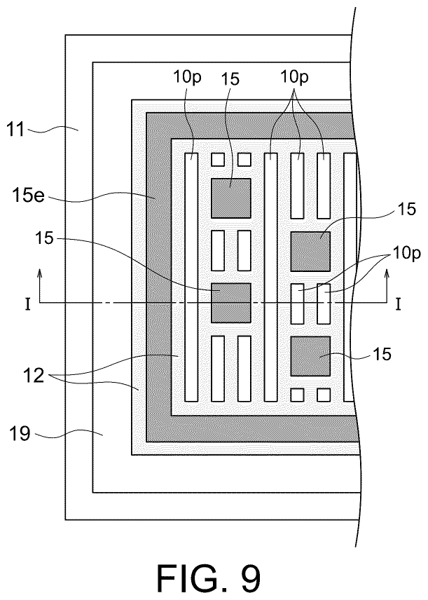

The high-concentration anode regions 15 and 15e are p⁺-type semiconductor regions provided in the anode regions 12. The impurity concentrations of p-type impurities in the high-concentration anode regions 15 and 15e are higher than the impurity concentration in the anode regions 12 and are, for example, between 1×10¹⁹ cm⁻³ and 1×10²¹ cm⁻³ (both inclusive). The high-concentration anode regions 15 and 15e are formed after formation of the anode regions 12, for example, by ion-implanting the trench bottoms with p-type impurities using a mask designed to expose part of the trench bottoms. The high-concentration anode regions 15 are, for example, rectangular in shape in planar view. The high-concentration anode region 15e is provided in an outer periphery of the anode regions 12, surrounding an element region including the high-concentration anode regions 15 (see FIG. 9).

The reduced surface field region 19 is a p-type semiconductor region provided in the SiC layer 10 to improve withstand voltage of the semiconductor device 1. The impurity concentration of p-type impurities in the reduced surface field region 19 is lower than the impurity concentration of p-type impurities in the anode regions 12, and is, for example, between 1×10¹⁶ cm⁻³ and 1×10¹⁸ cm⁻³ (both inclusive). The reduced surface field region 19 is electrically connected with the anode electrode 20.

The silicide layers 16 are provided between the high-concentration anode regions 15 and 15e and the anode electrode 20. The silicide layers 16 are made, for example, of nickel silicide. The silicide layers 16 are provided to reduce resistance between the anode regions 12 and the anode electrode 20. The silicide layers 16 are formed by a sputtering process or the like after formation of the anode regions 12 and high-concentration anode regions 15 and 15e.

Note that an n-type buffer layer (not illustrated) with an intermediate concentration in terms of the impurity concentration of n-type impurities between the impurity concentration of the drift region 11 and the impurity concentration of the cathode region 14 may be provided between the drift region 11 and the cathode region 14. The high-concentration anode regions 15 and 15e and/or the silicide layers 16 may be omitted.

Next, effects achieved by the Schottky characteristics adjusters 13 will be described with reference to FIGS. 3 and 4. FIG. 3 shows I_{F}-V_{F} characteristics of a Schottky barrier diode (SBD) when the Schottky characteristics adjusters 13 are not provided. In FIG. 3, a characteristic C1 is an I_{F}-V_{F} characteristic of a Schottky junction on the top face 10pt of the protrusion 10p and a characteristic C2 is an I_{F}-V_{F} characteristic of a Schottky junction on the side faces 10ps of the protrusion 10p. FIG. 4 shows I_{F}-V_{F} characteristic of SBD on the semiconductor device according to the present embodiment.

In the SiC layer 10, the Schottky junctions on the side faces 10ps are larger in Schottky barrier height than the Schottky junction on the top face 10pt of the silicon plane. For example, if the SiC layer 10 is made of 4H-SiC and the anode electrode 20 is made of titanium, Schottky barrier height on the carbon plane is 1.30 eV and the Schottky barrier height on the silicon plane is 1.17 eV. The value of the Schottky barrier height on the side faces 10ps is between 1.17 eV and 1.30 eV. Since the Schottky barrier height is larger on the side faces 10ps than on the top face 10pt, in a structure not provided with the Schottky characteristics adjusters 13, a rising voltage Vₜₕ₂ of SBD on the side faces 10ps is higher than a rising voltage Vₜₕ₁ of SBD on the top face 10pt as shown in FIG. 3. Forward voltage is also higher on the side faces 10ps than on the top face 10pt.

In contrast, in the semiconductor device 1 according to the present embodiment, the Schottky characteristics adjusters 13 made of an n⁺-type semiconductor region are provided in the side faces 10ps. This reduces the Schottky barrier height on the side faces 10ps. Consequently, the rising voltage Vₜₕ₂ of SBD on the side faces 10ps becomes almost equal to the rising voltage Vₜₕ₁ as shown in FIG. 4.

Thus, the present embodiment can provide a Schottky barrier diode which, being capable of reducing dispersions in the rising voltage and forward voltage between the top faces 10pt and the side faces 10ps, has excellent uniformity characteristics of both the rising voltage and forward voltage.

### Second Embodiment

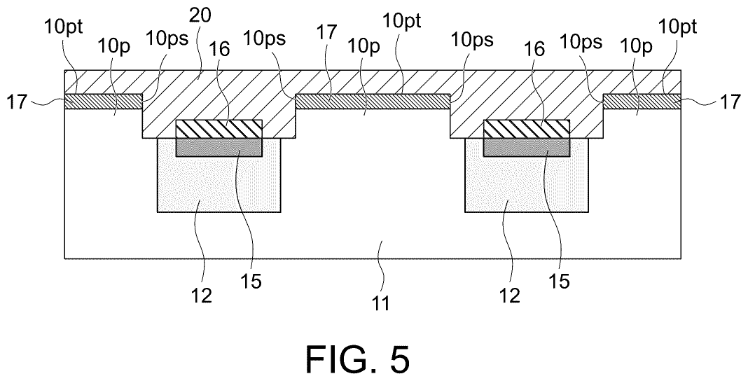

Next, a semiconductor device according to a second embodiment will be described with reference to FIG. 5. In the present embodiment, instead of reducing the Schottky barrier height on the side faces 10ps, the Schottky barrier height on the top faces 10pt is increased.

An overall schematic configuration of the semiconductor device according to the second embodiment is the same as in FIG. 1 referred to in the first embodiment. FIG. 5 is a cross sectional view showing a characteristic part (area corresponding to FIG. 2) of the semiconductor device according to the present embodiment.

As shown in FIG. 5, according to the second embodiment, instead of the Schottky characteristics adjusters 13 described in the first embodiment, Schottky characteristics adjusters 17 are provided in the top faces 10pt of the protrusions 10p. The Schottky characteristics adjusters 17 are p-type or p⁺-type semiconductor regions located between the anode electrode 20 and those parts of the drift region 11 which are inside the protrusions 10p.

The impurity concentration of p-type impurities in the Schottky characteristics adjusters 17 is, for example, between 1×10¹⁶ cm⁻³ and 1×10²⁰ cm⁻³ (both inclusive). The Schottky characteristics adjusters 17 are an example of a fourth semiconductor region described in CLAIMS. The Schottky characteristics adjusters 17 are formed by ion-implanting the top faces 10pt of the protrusions 10p with p-type impurities.

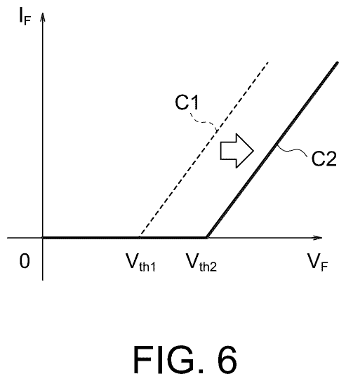

FIG. 6 shows I_{F}-V_{F} characteristic of SBD on the semiconductor device according to the second embodiment. As shown in FIG. 6, the Schottky characteristics adjusters 17 increase the Schottky barrier height on the top faces 10pt, thereby making the rising voltage Vₜₕ₁ of SBD on the top faces 10pt almost equal to the rising voltage Vₜₕ₂ of SBD on the side faces 10ps. Thus, the present embodiment can provide a Schottky barrier diode capable of reducing dispersions in the rising voltage and forward voltage.

### Third Embodiment

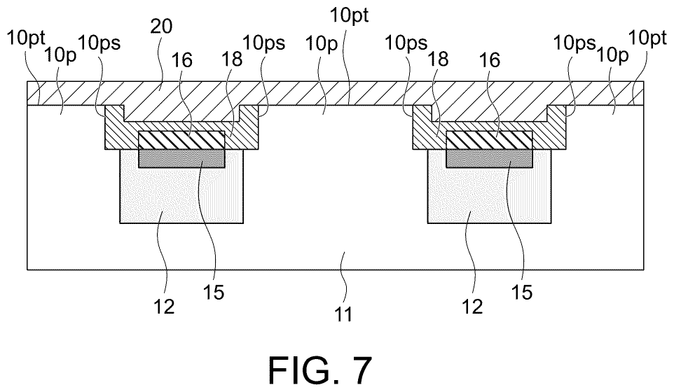

Next, a semiconductor device according to a third embodiment will be described with reference to FIG. 7. In the present embodiment, instead of providing semiconductor regions in the protrusions 10p, conductive parts are provided among the protrusions 10p (in the trenches).

An overall schematic configuration of the semiconductor device according to the third embodiment is the same as in FIG. 1 referred to in the first embodiment. FIG. 7 is a cross sectional view showing a characteristic part (area corresponding to FIG. 2) of the semiconductor device according to the present embodiment.

As shown in FIG. 7, according to the third embodiment, instead of the Schottky characteristics adjusters 13 described in the first embodiment, Schottky characteristics adjusters 18 are provided, covering the side faces 10ps of the protrusions 10p. The Schottky characteristics adjusters 18 are located between the anode electrode 20 and those parts of the drift region 11 which are inside the protrusions 10p.

The Schottky characteristics adjusters 18 are conductive parts made of a conductive material with a smaller work function than the anode electrode 20. The conductive parts are made, for example, of vanadium or titanium silicide. In the present embodiment, the Schottky characteristics adjusters 18 are provided covering the space between the protrusions 10p (i.e., the inner parts of the trenches) as shown in FIG. 7.

The Schottky characteristics adjusters 18 according to the present embodiment are formed, after formation of the anode regions 12, high-concentration anode regions 15, and silicide layers 16, for example, by covering the top surface 10a of the SiC layer 10 with a masking material in which an opening is provided between each pair of the protrusions 10p and depositing a conductive material using a sputtering process, a chemical-vapor deposition (CVD) process, or the like. As shown in FIG. 7, conductive parts are formed, covering side faces 10ps of the protrusions 10p, the anode regions 12, and the silicide layers 16. Note that the Schottky characteristics adjusters 18 do not have to cover the anode regions 12, and it is sufficient if the Schottky characteristics adjusters 18 are designed to cover at least the side faces 10ps of the protrusions 10p.

The Schottky characteristics adjusters 18 reduce the Schottky barrier height on the side faces 10ps of the protrusions 10p. Consequently, as with the first embodiment, the rising voltage Vₜₕ₂ of SBD on the side faces 10ps falls and becomes almost equal to the rising voltage Vₜₕ₁ of SBD on the top faces 10pt. Thus, the present embodiment can provide a Schottky barrier diode capable of reducing dispersions in the rising voltage and forward voltage.

As described above, in the first to third embodiments, the Schottky characteristics adjusters 13, 17, and 18 that combine the characteristic of the Schottky junction on the side faces 10ps of the protrusions 10p and the characteristic of the Schottky junction on the top faces 10pt are provided between the anode electrode 20 and those parts of the drift region 11 which are inside the protrusions 10p. This makes it possible to provide a Schottky barrier diode which, being capable of reducing dispersions in the rising voltage and forward voltage between the top faces 10pt and the side faces 10ps, has excellent uniformity characteristics of both the rising voltage and forward voltage.

Note that the Schottky characteristics adjusters 13, 17, and 18 according to the first to third embodiments may be combined in any desired manner. For example, both the Schottky characteristics adjuster 13 and the Schottky characteristics adjuster 17 may be provided. Alternatively, at least one of the Schottky characteristics adjuster 13 and Schottky characteristics adjuster 17 may be provided together with the Schottky characteristics adjuster 18. When the Schottky characteristics adjuster 13 is provided in this way, the Schottky characteristics adjuster 13 is mounted between the Schottky characteristics adjuster 18 and those parts of the drift region 11 which are inside the protrusions 10p.

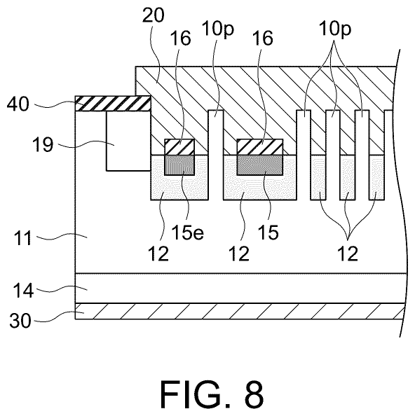

The semiconductor device to which the Schottky characteristics adjusters described above are applied is not limited to the semiconductor device, the configuration of which is shown in FIG. 1. FIG. 8 shows a partial section of another applicable semiconductor device. FIG. 9 is a plan view of the semiconductor device shown in FIG. 8. FIG. 8 is a cross sectional view taken along line I-I of FIG. 9. In such a semiconductor device, the Schottky characteristics adjuster 13 may be provided in the side faces of the protrusions 10p, the Schottky characteristics adjuster 18 may be provided on the side faces of the protrusions 10p or the Schottky characteristics adjuster 17 may be provided in the top faces of the protrusions 10p.

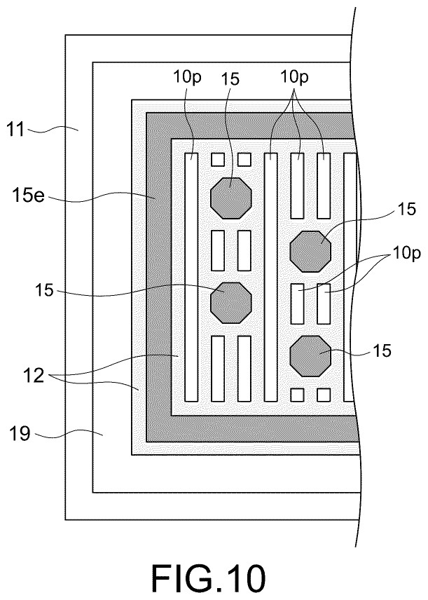

As shown in FIG. 9, the high-concentration anode regions 15 have a rectangular shape in planar view. The planar shape of the high-concentration anode regions 15 is not limited to this, and may be, for example, a regular octagonal shape as shown in FIG. 10.

With the semiconductor device according to at least one of the embodiments described above, there is provided a semiconductor device that has high withstand voltage and can reduce dispersions in the rising voltage and forward voltage.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor device comprising:
a SiC layer, which includes a first surface and a second surface, the first surface being made up of a silicon plane, the second surface being made up of a carbon plane and placed opposite the first surface;
a plurality of protrusions provided in the SiC layer, each of the protrusions including a top face and side faces, the top face being part of the first surface, the side faces being connected to the top face;
a first electrode that forms Schottky junctions with the plurality of protrusions;
a second electrode provided on the second surface;
a first semiconductor region of a first conductivity type provided in the SiC layer;
a second semiconductor region of a second conductivity type provided among the plurality of protrusions in the SiC layer and located between the first semiconductor region and the first electrode; and
a third semiconductor region of the first conductivity type provided in the side faces of the protrusions and located between the first electrode and the first semiconductor region in the protrusions, the third semiconductor region being higher in impurity concentration of the first conductivity type than the first semiconductor region.

2. The semiconductor device according to claim 1, wherein the first electrode includes titanium, molybdenum, vanadium, nickel, or a laminated film of titanium and aluminum.

3. The semiconductor device according to claim 1, further comprising a seventh semiconductor region of the second conductivity type provided in the second semiconductor region, the seventh semiconductor region being higher in impurity concentration of the second conductivity type than the second semiconductor region.

4. The semiconductor device according to claim 3, further comprising a silicide layer provided between the seventh semiconductor region and the first electrode.

5. A semiconductor device comprising:
a SiC layer, which includes a first surface and a second surface, the first surface being made up of a silicon plane, the second surface being made up of a carbon plane and placed opposite the first surface;
a plurality of protrusions provided in the SiC layer, each of the protrusions including a top face and side faces, the top face being part of the first surface, the side faces being connected to the top face;
a first electrode that forms Schottky junctions with the plurality of protrusions;
a second electrode provided on the second surface;
a first semiconductor region of a first conductivity type provided in the SiC layer;
a second semiconductor region of a second conductivity type provided among the plurality of protrusions in the SiC layer and located between the first semiconductor region and the first electrode; and
a fourth semiconductor region of the second conductivity type provided in the top face of each of the protrusions and located between the first electrode and the first semiconductor region in the protrusions.

6. The semiconductor device according to claim 5, wherein the first electrode includes titanium, molybdenum, vanadium, nickel, or a laminated film of titanium and aluminum.

7. The semiconductor device according to claim 5, further comprising a seventh semiconductor region of the second conductivity type provided in the second semiconductor region, the seventh semiconductor region being higher in impurity concentration of the second conductivity type than the second semiconductor region.

8. The semiconductor device according to claim 7, further comprising a silicide layer provided between the seventh semiconductor region and the first electrode.

9. A semiconductor device comprising:
a SiC layer, which includes a first surface and a second surface, the first surface being made up of a silicon plane, the second surface being made up of a carbon plane and placed opposite the first surface;
a plurality of protrusions provided in the SiC layer, each of the protrusions including a top face and side faces, the top face being part of the first surface, the side faces being connected to the top face;
a first electrode that forms Schottky junctions with the plurality of protrusions;
a second electrode provided on the second surface;
a first semiconductor region of a first conductivity type provided in the SiC layer;
a second semiconductor region of a second conductivity type provided among the plurality of protrusions in the SiC layer and located between the first semiconductor region and the first electrode; and
a conductive part formed, covering at least the side faces of the protrusions, with a smaller work function than the first electrode.

10. The semiconductor device according to claim 9, wherein the conductive part contains vanadium or titanium silicide.

11. The semiconductor device according to claim 9, further comprising a fifth semiconductor region of the first conductivity type provided in the side faces of the protrusions and located between the conductive part and the first semiconductor region in the protrusions, the fifth semiconductor region being higher in impurity concentration of the first conductivity type than the first semiconductor region.

12. The semiconductor device according to claim 9, further comprising a sixth semiconductor region of the second conductivity type provided in the top face of each of the protrusions and located between the first electrode and the first semiconductor region in the protrusions.

13. The semiconductor device according to claim 9, wherein the first electrode includes titanium, molybdenum, vanadium, nickel, or a laminated film of titanium and aluminum.

14. The semiconductor device according to claim 9, further comprising a seventh semiconductor region of the second conductivity type provided in the second semiconductor region, the seventh semiconductor region being higher in impurity concentration of the second conductivity type than the second semiconductor region.

15. The semiconductor device according to claim 14, further comprising a silicide layer provided between the seventh semiconductor region and the first electrode.
